(19) United States
(12) Patent Application Publication
(10) Pub. No.: US 2002/0184583 A1
(43) Pub. Date: Dec. 5, 2002

(54) Cell having scan functions and a test circuit of a semiconductor integrated circuit

(75) Inventors: Kazunori Hikone, Naka (JP); Kiyoshi Alki, Hachioji (JP)

Correspondence Address: Stanley P. Fisher, Reed Smith LLP, Suite 1400, 3110 Fairview Park Drive, Falls Church, VA, 22042-4503, US

(73) Assignee: Hitachi, Ltd.

(21) Appl. No.: 10/153,743

(22) Filed: May 24, 2002

(30) Foreign Application Priority Data
Jun. 4, 2001 (JP) 2001-168226

(51) Int. Cl. G01R 31/28

(52) U.S. Cl. 714/726

(57) ABSTRACT

To reduce test time, test circuit configuration in which the parallel execution of a test of an I/O device and a test of an internal circuit is enabled in a semiconductor integrated circuit provided with scan test functions and a test method are provided. A test is made by a test circuit having an operational mode composed of a scan path used for observing a value of a signal fetched from an external terminal by an input buffer and setting the output value of an output buffer and a scan path used for setting a value of a signal applied to the internal circuit and observing a value of a signal output from the internal circuit in addition to a normal boundary scan operational mode. Hereby, as the test of the I/O device and the test of the internal circuit can be executed in parallel, test time can be reduced.

### FIELD OF THE INVENTION

The present invention relates to a semiconductor integrated circuit provided with scan test functions, particularly relates to test technique used for a manufacturing test of a semiconductor integrated circuit.

### BACKGROUND OF THE INVENTION

As a semiconductor integrated circuit is large-sized, the cost for a manufacturing test of a manufactured semiconductor integrated circuit increases. To reduce the cost of the test, Built-In Self-Test (BIST) technique for realizing a test circuit based upon scan test functions and a self-test function to facilitate applying and observing a test signal to/in an I/O buffer and an area under a test in the circuit is published.

For a test circuit for realizing scan test functions, there are a boundary scan method standardized in IEEE1149.1 and a core test technique discussed for standardization as IEEE P1500.

FIG. 2 shows an example of a cell having scan functions used in the boundary scan method or core test technique. The cell having scan functions is provided with a storage element 1 for storing a signal and a storage element 2 for setting a signal output from an output terminal PO inside and is provided with a function for fetching a signal input from an input terminal PI in the internal storage element 1, a function for fetching a signal input from an input terminal for test SI in the storage element 1, a function for transferring the signal fetched in the storage element 1 to the storage element 2 and outputting the signal stored in the storage element 2 to the output terminal PO and a function for outputting the signal fetched in the storage element 1 to an output terminal for test SO in addition to a function for outputting the signal input from the input terminal PI to the output terminal PO.

In a normal mode in which no test is made, a signal input from the input terminal PI is output to the output terminal PO. In a test mode in which a test is made, an input signal is observed by fetching a signal input from the input terminal PI and outputting the signal from the output terminal for test SO, an output signal is set by fetching a signal input from the input terminal for test SI and outputting the signal from the output terminal PO, and observed signals and signals to be set are transferred by fetching the signal input from the input terminal for test SI and outputting the signal from the output terminal for test SO, respectively using the functions of the cell.

In a scan test, test data is set and observed by serially connecting the input terminals for test and the output terminals for test of the cells having scan functions. A path for setting and observing test data is called a scan path.

The boundary scan circuit is a test circuit in which a cell having scan functions called a boundary scan cell is inserted between an I/O buffer and an internal circuit respectively of a semiconductor integrated circuit as shown in FIG. 3 for setting and observing a signal from an input terminal for test TDI to an output terminal for test TDO via one scan path. A reference number 30 denotes an input external terminal of the semiconductor integrated circuit, 31 denotes an input buffer, 32 denotes a boundary scan cell for input, 33 denotes the internal terminal, 34 denotes a boundary scan cell for output, 35 denotes an output buffer, 36 denotes an output external terminal and 37 denotes a bi-directional external terminal.

For a function for testing the inside of the integrated circuit using the boundary scan circuit, there is an INTEST mode. The INTEST mode is a mode for applying a signal to the internal circuit and observing an output value without passing the input buffer, the output buffer and a bi-directional buffer. As shown in FIG. 4, test data is set in the boundary scan cell for input 32 from the input terminal for test TDI via the scan path, a function for supplying a signal to the internal circuit 33 and an output signal from the internal circuit are fetched in the boundary scan cell for output 34, a function for observing in the output terminal for test TDO via the scan path is executed and the internal circuit 33 is tested.

For a function for enabling executing the test of an I/O device from the I/O buffer to the external terminal using a boundary scan, there is an EXTEST mode.

In the EXTEST mode, as shown in FIG. 5, an input signal input from an input external terminal 30 or a bi-directional external terminal 37 via an input buffer 31 is fetched in a boundary scan cell for input 32 and observed at the output terminal for test TDO via the scan path and test data via the scan path from the input terminal for the test TDI are set in the boundary scan cell for output 34 and an output signal is applied to the output buffer 35 and output from the bi-directional external terminal 37 or the output external terminal 36 and a test is made.

The setting and observation of a signal value in the I/O buffer are facilitated and a test of the internal circuit is enabled without passing the I/O buffer respectively by making the test using such a boundary scan circuit, however, as only one scan path is provided and the scan path provided for the boundary scan circuit is also one, the INTEST mode and the EXTEST mode become exclusive and there is a problem that the test of the I/O device and the internal circuit which are respectively different as an object of a test cannot be simultaneously executed.

For another example of the test circuit utilizing scan test functions, core test technique discussed for standardization as IEEE P1500 will be described below. In core test technique, an area under a test is called a core, an access mechanism from the outside of a semiconductor integrated circuit to input/output signal terminals of the core is provided and a test of the core is made. FIG. 6 shows the outline of core test technique. For a test circuit that sets and observes an input/output signal to/from the core, a cell having scan functions and called a wrapper cell is added to an input terminal and an output terminal of the core.

A test of a core 1 is executed by setting an input signal to the core 1 from an external terminal 55 via a test access mechanism 54 and a scan path 52 and observing an output signal from an external terminal 56 via the test access mechanism 54.

A test of a core 2 is executed by setting an input signal to the core 2 from the external terminal 55 via the test access mechanism 54 and a scan path 53 and observing an output signal from the external terminal 56 via the test access mechanism 54.

A test of an area between the core 1 and the core 2 is executed by setting an output signal and observing an input signal of core 1 from the external terminal 55 via the test access mechanism 54, the scan path 52, the test access mechanism 54 and the external terminal 56 and by setting an output terminal and observing an input signal of core 2 from the external terminal 55 via the test access mechanism 54, the scan path 53, the test access mechanism 54 and the external terminal 56 as shown in FIG. 7.

In core test technique, only one scan path is also provided to the wrapper cell and there is a problem that a test of the core and a test between the cores cannot be simultaneously executed.

Conventional type BIST technique is discussed in “A Tutorial on Built-In Self-Test” on the 73rd to the 82nd pages of the March issue in 1993 of “IEEE DESIGN & TEST OF COMPUTERS” and on the 69th to the 77th pages of the June issue in 1993 of the same. BIST is composed of a test controller, a pattern generator and a response analyzer as shown in FIG. 8. It is determined by inputting a signal output by the pattern generator to an area under a test, fetching a response signal of it in the response analyzer and observing a state of the response analyzer whether there is failure or not. This operation is controlled by the test controller, however, the test can be automatically executed by describing a series of test operation in the test controller.

However, even if the BIST technique is applied to an internal circuit of a semiconductor integrated circuit using a boundary scan circuit and is applied to a core according to core test technique, a test of an I/O device and a test of the internal circuit, and a test of the circuit between cores and a test of the core cannot be simultaneously executed.

To reduce the cost of a test, the reduction of test time is desired. Therefore, in case tests of different parts as an object of a test are simultaneously executed, a boundary scan and core test technique described as the examples of prior art have a problem that the parallel execution of a test of the I/O device and a test of the internal circuit and the parallel execution of a test of the core and a test of the circuit between the cores are disabled.

### SUMMARY OF THE INVENTION

The object of the invention is to provide test circuit configuration in which the parallel execution of a test of an I/O device and a test of an internal circuit and the parallel execution of a test of a core and a test between cores are enabled and a test method in a semiconductor integrated circuit provided with scan test functions to reduce test time.

To solve the problems, a cell having scan functions which is a test circuit according to the invention is characterized in that the cell can execute the observation of data input to the cell and the setting of data output from the cell in parallel by having a scan path for observing data input to the cell and a scan path for setting data output from the cell.

Also, a boundary scan circuit is characterized in that the boundary scan circuit is a test circuit that can execute a test of an I/O device and a test of an internal circuit in parallel by having an operation mode including a scan path used for observing a value of a signal fetched from an external terminal by an input buffer and setting the output value of an output buffer and a scan path used for setting a value of a signal applied to the internal circuit and observing a value of a signal output from the internal circuit in addition to a normal boundary scan operation mode.

Also, a scan path forming a scan circuit located on a boundary of a test area to set and observe a signal input to the area under the test and a signal output from the area under the test is characterized in that the scan path is a test circuit in which a test of an area under a test and a test between areas under tests can be executed in parallel by including a scan path used for observing a signal input to the area under the test from the outside of the area under the test and setting an output signal in place of a signal output from the area under the test to the outside of the area under the test and a scan path used for observing a signal output from the area under the test to the outside of the area under the test and setting an input signal in place of a signal input to the area under the test from the outside of the area under the test.

Also, a test method of enabling the parallel execution of a test of the I/O device and a test of the internal circuit is characterized in that the test method is enabled by using the scan path used for observing a value of a signal fetched from the external terminal by the input buffer and setting the output value of the output buffer for the test of the I/O device and using the scan path used for setting a value of a signal applied to the internal circuit and observing a value of a signal output from the internal circuit for the test of the internal circuit.

### BRIEF DESCRIPTION OF THE DRAWINGS

FIG. 1 is an explanatory drawing for explaining one embodiment of a cell having scan functions according to the invention;

FIG. 2 is an explanatory drawing for explaining an example of a conventional type cell having scan functions;

FIG. 3 is an explanatory drawing for explaining an example of a conventional type boundary scan circuit;

FIG. 4 shows the operation of the boundary scan circuit;

FIG. 5 shows the operation of the boundary scan circuit;

FIG. 6 shows the operation of an example of conventional type core test technique;

FIG. 7 shows the operation of the example of the conventional type core test technique;

FIG. 8 is an explanatory drawing for explaining an example of conventional type BIST technique;

FIG. 9 is a circuit diagram showing one example of the concrete configuration of the embodiment shown in FIG. 1;

FIG. 10 is a circuit diagram showing another example of the concrete configuration of the embodiment shown in FIG. 1;

FIG. 11 is an explanatory drawing for explaining another embodiment of the cell having scan functions according to the invention;

FIG. 12 is a circuit diagram showing one example of the concrete configuration of the embodiment shown in FIG. 11;

FIG. 13 is a circuit diagram showing another example of the concrete configuration of the embodiment shown in FIG. 11;

FIG. 14 is a circuit diagram showing further another example of the concrete configuration of the embodiment shown in FIG. 11;

FIG. 15 shows an example in which the cell having scan functions and shown in FIG. 9 is formed by two cells;

FIG. 16 shows one embodiment of a test circuit according to the invention;

FIG. 17 shows another embodiment of the test circuit according to the invention;

FIG. 18 shows further another embodiment of the test circuit according to the invention;

FIG. 19 is an explanatory drawing for explaining an example in which the embodiment shown in FIG. 1 is applied to core test technique; and

FIG. 20 is an explanatory drawing for explaining an example of configuration that a BIST circuit is connected to the embodiment shown in FIG. 16.

### DETAILED DESCRIPTION OF THE PREFERRED EMBODIMENTS

Embodiments of the invention will be described below.

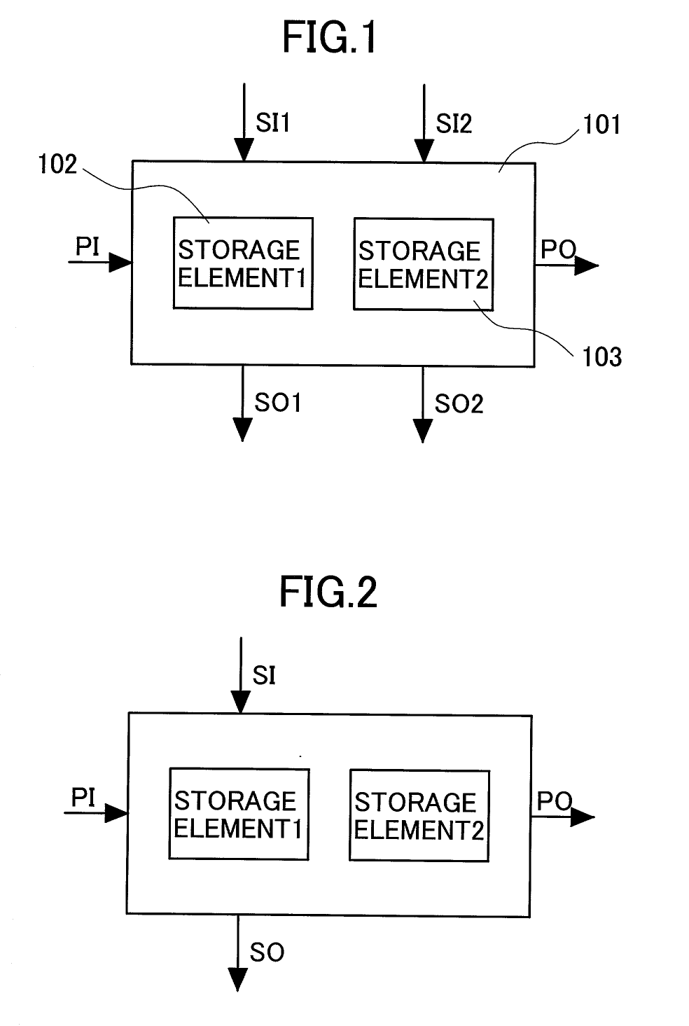

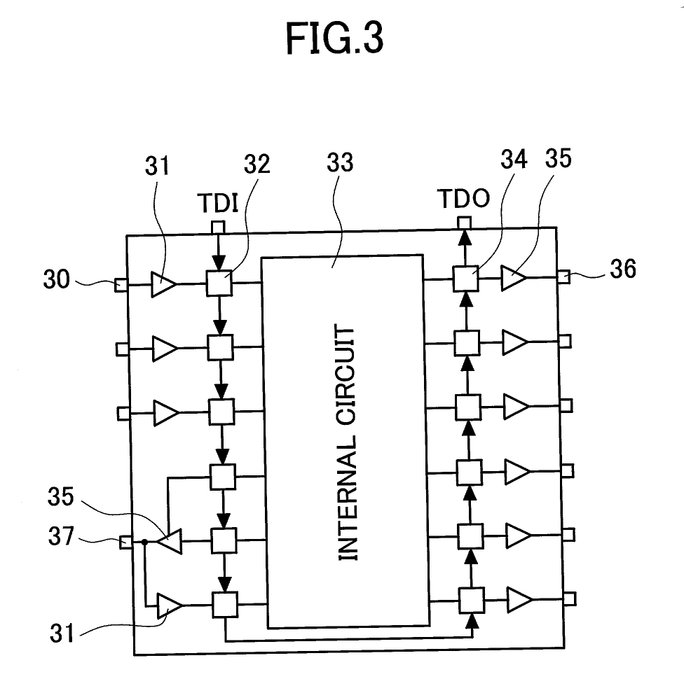

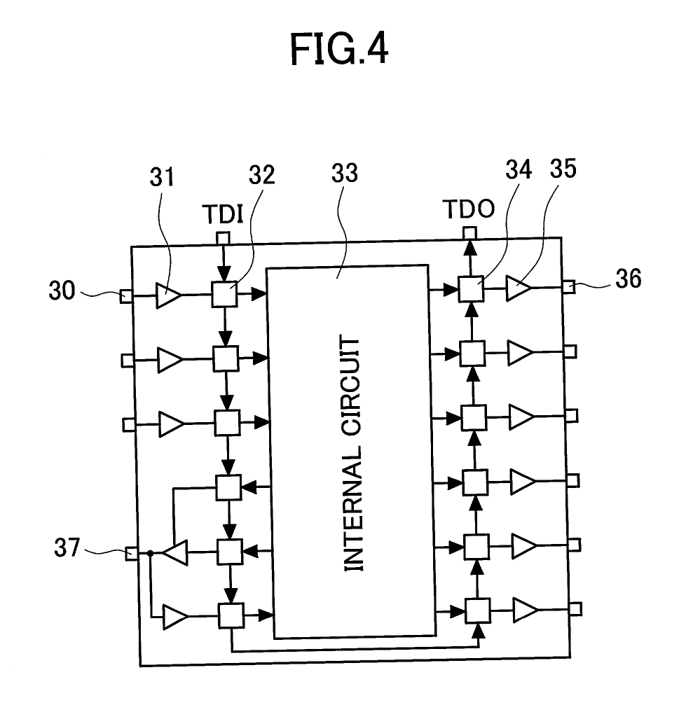

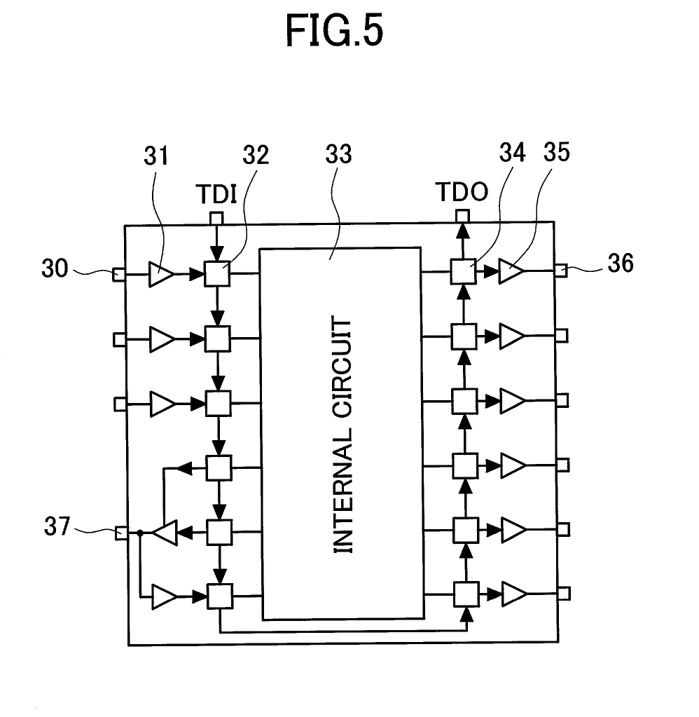

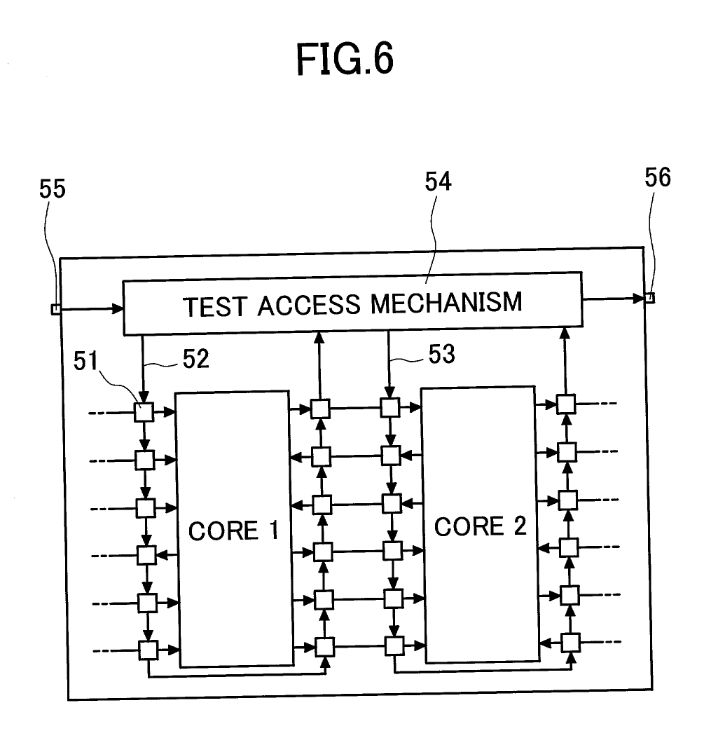

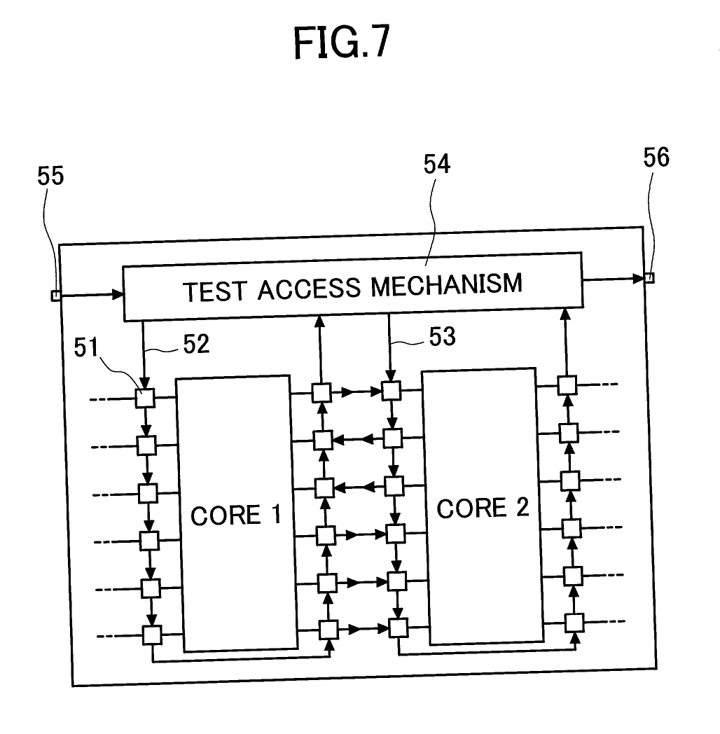

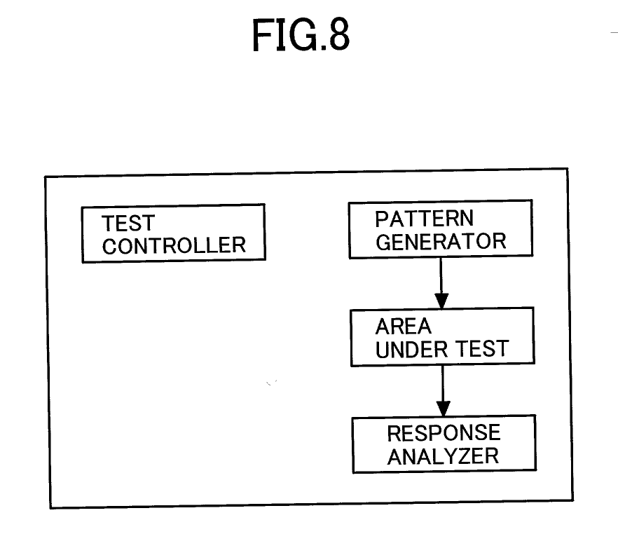

FIG. 1 shows the configuration of a cell having scan functions equivalent to one embodiment of the invention. A reference number 101 denotes the cell having scan functions, PI denotes an input terminal, PO denotes an output terminal, SI1 denotes an input terminal for test, SI2 denotes an input terminal for test, SO1 denotes an output terminal for test, SO2 denotes an output terminal for test, 102 denotes a storage element for storing a signal input from PI and a signal input from SI1 and 103 denotes a storage element for storing a signal input from SI2 and setting a signal output from PO. The cell having scan functions 101 is provided with a function for outputting the signal input from PI to PO, a function for storing the signal input from PI in the storage element 102, a function for storing the signal input from SI1 in the storage element 102, a function for outputting the signal stored in the storage element 102 to SO1, a function for storing the signal input from SI2 in the storage element 103, a function for outputting the signal stored in the storage element 103 to PO and a function for outputting the signal stored in the storage element 103 to SO2.

In a normal operational mode in which no test is made in this embodiment, a signal input from PI is output to PO. The operation in a test mode in which a test is made will be described below.

For operation for observing a signal input from PI, a signal input from PI is first stored in the storage element 102 and next, the signal stored in the storage element 102 is output to SO1. For operation for transferring a signal input from SI1 to SO1, a signal input from SI1 is first stored in the storage element 102 and next, the signal stored in the storage element 102 is output to SO1. For operation for setting a signal output from PO, a signal input from SI2 is first stored in the storage element 103 and next, the signal stored in the storage element 103 is output to PO. For operation for transferring a signal input from SI2 to SO2, a signal input from SI2 is first stored in the storage element 103 and next, the signal stored in the storage element 103 is output to SO2.

The operation for observing the signal input from PI is called input signal observing operation, the operation for transferring the signal input from SI1 to SO1 is called observed signal transferring operation, the operation for setting the signal output from PO is called output signal setting operation, the operation for transferring the signal input from SI2 to SO2 is called output signal transferring operation, a signal path from SI1 to SO1 is called an input data observing scan path and a signal path from SI2 to SO2 is called an output data setting scan path.

In the configuration in this embodiment, as the input data observing scan path and the output data setting scan path pass different storage elements and are also different in an input terminal for test and an output terminal for test, the observed signal transferring operation and the output signal setting operation can be independently executed, and similarly, the input signal observing operation and the output signal setting operation can be independently executed. Also, the observed signal transferring operation and the output signal transferring operation can be independently executed, and similarly, the input signal observing operation and the output signal transferring operation can be independently executed.

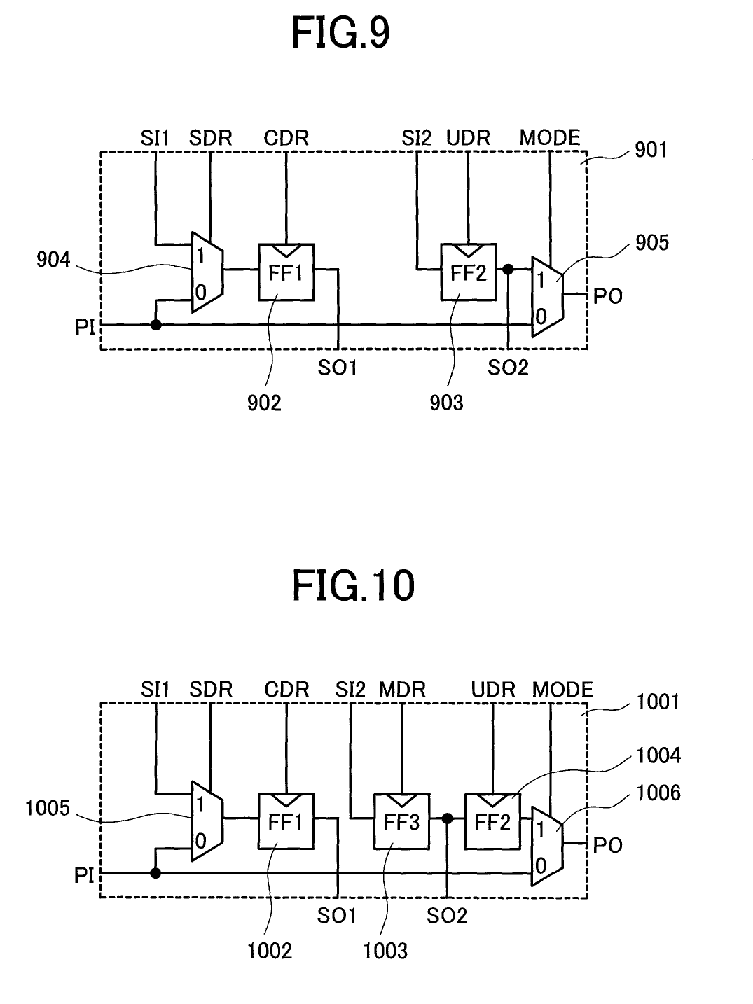

FIG. 9 shows a concrete example of the configuration in the embodiment shown in FIG. 1. A reference number 901 denotes a cell having scan functions, PI denotes an input terminal, PO denotes an output terminal, SI1 denotes an input terminal for test, SI2 denotes an input terminal for test, SO1 denotes an output terminal for test, SO2 denotes an output terminal for test, 902 denotes a flip-flop for storing a signal input from PI and a signal input from SI1, CDR denotes a terminal for inputting a clock signal to the flip-flop 902, 903 denotes a flip-flop for storing a signal input from SI2, UDR denotes a terminal for inputting a clock signal to the flip-flop 903, 904 denotes a multiplexer for switching storing a signal input from PI in the flip-flop 902 and storing a signal input from SI1 in the flip-flop 902, SDR denotes a terminal for inputting a control signal for selection in the multiplexer 904, 905 denotes a multiplexer for switching the normal operational mode in which a signal input from PI is output to PO and the test mode and MODE denotes a terminal for inputting a control signal for selection in the multiplexer 905.

The multiplexer in the description of the invention shall output a signal at a terminal 1 when ‘1’ is input to its control input terminal and shall output a signal at a terminal 0 when ‘0’ is input to the control input terminal.

To turn the cell having scan functions 901 to the normal operational mode, ‘0’ is applied to the MODE terminal and a signal path for transmitting a signal input from PI to PO is selected. In the test mode in which a test is made, after ‘1’ is applied to the MODE terminal so that the effect of a signal input from PI is not transmitted to PO and a signal stored in the flip-flop 903 is transmitted to PO, the following operation is executed.

To execute input signal observing operation, first, ‘0’ is applied to SDR so that a signal from PI is transmitted to the flip-flop 902 via the multiplexer 904, next, a clock is applied to CDR so that the signal from PI is stored in the flip-flop 902 and the stored signal is output to SO1. To execute observed signal transferring operation, first, ‘1’ is applied to SDR so that a signal from SI1 is transmitted to the flip-flop 902 via the multiplexer 904, next, a clock is applied to CDR so that a signal from SI1 is stored in the flip-flop 902 and the stored signal is output to SO1. To execute output signal setting operation and output signal transferring operation, a clock is applied to UDR so that a signal from SI2 is stored in the flip-flop 903 and the stored signal is output to PO and SO2.

In the test mode, as the input data observing scan path from SI1 to SO1 and the output data setting scan path from SI2 to SO2 are different and are independent in relation to control, the observed signal transferring operation and the output signal setting operation can be independently executed and similarly, the input signal observing operation and the output signal setting operation can be independently executed. Also, the observed signal transferring operation and the output signal transferring operation can be independently executed, and similarly, the input signal observing operation and the output signal transferring operation can be independently executed.

FIG. 10 shows another concrete example of the configuration of the embodiment shown in FIG. 1. A reference number 1001 denotes a cell having scan functions, PI denotes an input terminal, PO denotes an output terminal, SI1 denotes an input terminal for test, SI2 denotes an input terminal for test, SO1 denotes an output terminal for test, SO2 denotes an output terminal for test, 1002 denotes a flip-flop for storing a signal input from PI and a signal input from SI1, CDR denotes a terminal for inputting a clock signal to the flip-flop 1002, 1003 denotes a flip-flop for storing a signal input from SI2, MDR is a terminal for inputting a clock signal to the flip-flop 1003, 1004 denotes a flip-flop for storing a signal output to PO, UDR denotes a terminal for inputting a clock signal to the flip-flop 1004, 1005 denotes a multiplexer for switching storing a signal input from PI in the flip-flop 1002 and storing a signal input from SI1 in the flip-flop 1002, SDR denotes a terminal for inputting a control signal for selection in the multiplexer 1005, 1006 denotes a multiplexer for switching the normal operational mode in which a signal input from PI is output to PO and the test mode and MODE denotes a terminal for inputting a control signal for selection in the multiplexer 1006.

The example shown in FIG. 10 of the configuration shows configuration in which the flip-flop for transfer and the flip-flop for setting an output signal are separately provided so that a signal output from PO is unchanged during output signal transferring operation based upon the example shown in FIG. 9 of the configuration. As control for turning to the normal operational mode, the input signal observing operation and the observed signal transferring operation respectively in the test mode are the same as those in the example shown in FIG. 9 of the configuration, the description is omitted.

For the output signal transferring operation in the test mode, after ‘1’ is applied to the MODE terminal so that the effect of a signal input from PI is not transmitted to PO and a signal stored in the flip-flop 1004 is transmitted to PO, a clock is applied to MDR so that a signal from SI2 is stored in the flip-flop 1003 and the stored signal is output to SO2. For the output signal setting operation in the test mode, after ‘1’ is applied to the MODE terminal so that the effect of a signal input from PI is not transmitted to PO and a signal stored in the flip-flop 1004 is transmitted to PO, a clock is applied to UDR so that a signal stored in the flip-flop 1003 is stored in the flip-flop 1004 and the stored signal is output to PO.

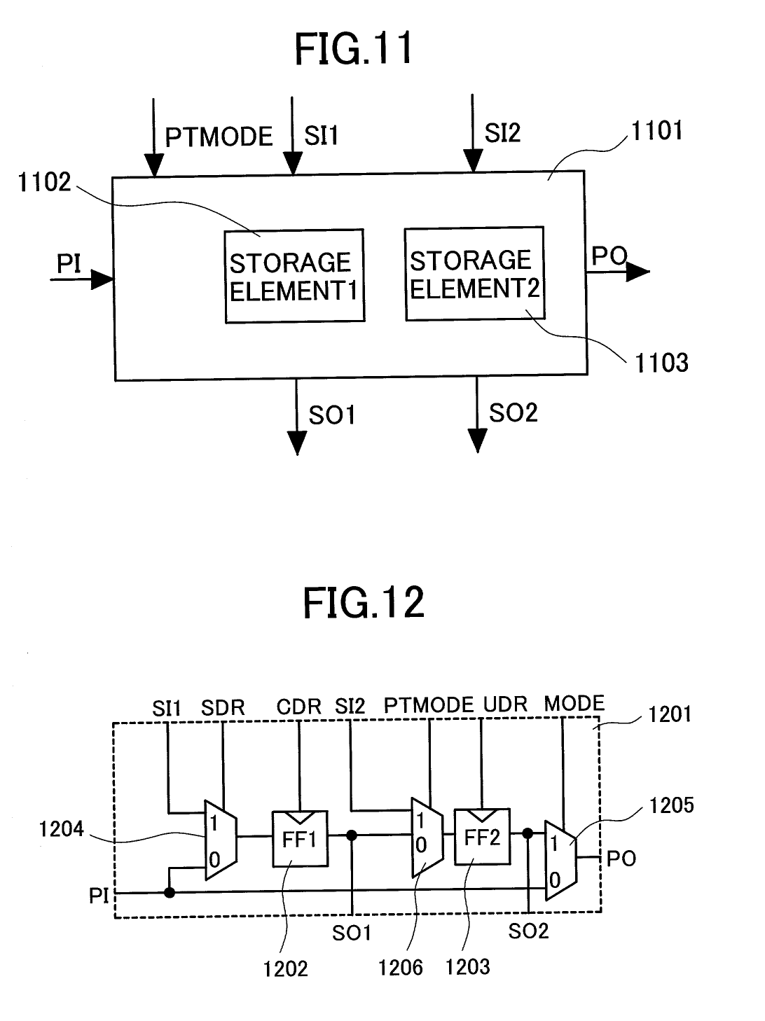

Next, another embodiment shown in FIG. 11 of the cell having scan functions according to the invention will be described. A reference number 1101 denotes a cell having scan functions, PI denotes an input terminal, PO denotes an output terminal, SI1 denotes an input terminal for test, SI2 denotes an input terminal for test, SO1 denotes an output terminal for test, SO2 denotes an output terminal for test, PTMODE is a terminal for inputting a control signal for switching an operational mode, 1102 denotes a flip-flop for storing a signal input from PI and a signal input from SI1 and 1103 denotes a flip-flop for storing a signal input from SI2 and a signal output from the flip-flop 1102.

The cell having scan functions 1101 is provided with a function for outputting a signal input from PI to PO, a function for storing the signal input from PI in the storage element 1102, a function for storing a signal input from SI1 in the storage element 1102, a function for outputting the signal stored in the storage element 1102 to SO1, a function for storing a signal input from SI2 in the storage element 1103, a function for outputting the signal stored in the storage element 1103 to PO, a function for outputting the signal stored in the storage element 1103 to SO2 and a function for transferring the signal stored in the storage element 1102 to the storage element 1103.

The cell having scan functions 1101 is also provided with a normal operational mode in which a signal input from PI is output to PO as an operational mode, a compatible mode with a boundary scan using PI, PO, SI1 and SO1 and a parallel test mode using PI, PO, SI1, SI2, SO1 and SO2 respectively as a test mode, and the compatible mode with a boundary scan and the parallel test mode are switched according to a signal input from a control signal input terminal PTMODE.

The operation in the compatible mode with a boundary scan will be described below. The compatible mode with a boundary scan is a mode in which operation similar to that of the cell having scan functions shown in the example of prior art is performed. For operation for observing a signal input from PI, first, a signal input from PI is stored in the storage element 1102 and next, the signal stored in the storage element 1102 is output to SO1. For operation for transferring a signal input from SI1 to SO1, first, a signal input from SI1 is stored in the storage element 1102 and next, the signal stored in the storage element 1102 is output to SO1. For operation for setting a signal output from PO, first, a signal input from SI1 is stored in the storage element 1102 using operation for transferring a signal input from SI1 to SO1, next, the signal stored in the storage element 1102 is transferred to the storage element 1103 and the signal stored in the storage element 1103 is output to PO. In the compatible mode with a boundary scan, SI2 and SO2 are not used for the test.

Next, the parallel test mode will be described. The parallel test mode is a mode in which operation similar to that of the test mode in the embodiment shown in FIG. 1 is performed. For operation for observing a signal input from PI, first, a signal input from PI is stored in the storage element 1102 and next, the signal stored in the storage element 1102 is output to SO1. For operation for transferring a signal input from SI1 to SO1, first, a signal input from SI1 is stored in the storage element 1102 and next, the signal stored in the storage element 1102 is output to SO1. For operation for setting a signal output-from PO, first, a signal input from SI2 is stored in the storage element 1103 and next, the signal stored in the storage element 1103 is output to PO. For operation for transferring a signal input from SI2 to SO2, first, a signal input from SI2 is stored in the storage element 1103 and next, the signal stored in the storage element 1103 is output to SO2.

In the configuration in this embodiment, as in the parallel test mode, an input data observing scan path from SI1 to SO1 and an output data setting scan path from SI2 to SO2 are formed by different terminals and different storage elements, observed signal transferring operation and output signal setting operation can be independently executed and similarly, input signal observing operation and output signal setting operation can be independently executed. Also, the observed signal transferring operation and the output signal transferring operation can be independently executed, and similarly, the input signal observing operation and the output signal transferring operation can be independently executed.

Also, as the compatible mode with a boundary scan in which the observing of an input signal and the setting of an output signal are performed via one scan path is included, a test circuit compatible with the conventional type boundary scan method can be created.

FIG. 12 shows a concrete example of the configuration of the embodiment shown in FIG. 11. A reference number 1201 denotes a cell having scan functions, PI denotes an input terminal, PO denotes an output terminal, SI1 denotes an input terminal for test, SI2 denotes an input terminal for test, SO1 denotes an output terminal for test, SO2 denotes an output terminal for test, 1202 denotes a flip-flop for storing a signal input from PI and a signal input from SI1, CDR denotes a terminal for inputting a clock signal to the flip-flop 1202, 1203 denotes a flip-flop for storing a signal input from SI2 or an output signal from the storage element 1202, UDR denotes a terminal for inputting a clock signal to the flip-flop 1203, 1204 denotes a multiplexer for switching storing a signal input from PI in the flip-flop 1202 and storing a signal input from SI1 in the flip-flop 1202, SDR denotes a terminal for inputting a control signal for selection in the multiplexer 1204, 1205 denotes a multiplexer for switching a normal operational mode in which a signal input from PI is output to PO and a test mode, MODE denotes a terminal for inputting a control signal for selection in the multiplexer 1205, 1206 denotes a multiplexer for switching storing a signal output from the flip-flop 1202 in the flip-flop 1203 and storing a signal input from SI2 in the flip-flop 1203 and PTMODE denotes a terminal for inputting a control signal for selection in the multiplexer 1206.

To turn the cell having scan functions 1201 to a normal operational mode, ‘0’ is applied to the MODE terminal and a signal path for transmitting a signal input from PI to PO is selected. To turn the cell having scan functions to a compatible mode with a boundary scan, ‘0’ is applied to the PTMODE terminal so that a path for transmitting a signal from the storage element 1202 to the storage element 1203 is selected and the effect of a signal input from SI2 on the storage element 1203 is removed. To turn the cell having scan functions to a parallel test mode, ‘1’ is applied to the PTMODE terminal so that a path for transmitting a signal input from SI2 to the storage element 1203 is selected and the effect of a signal output from the storage element 1202 on the storage element 1203 is removed.

Next, the operation in the compatible mode with a boundary scan will be described. For operation for observing a signal input from PI, first, ‘0’ is applied to SDR so that a signal from PI is transmitted to the flip-flop 1202 via the multiplexer 1204, next, a clock is applied to CDR so that a signal input from PI is stored in the flip-flop 1202 and the stored signal is output to SO1. For operation for transferring a signal input from SI1 to SO1, first, ‘1’ is applied to SDR so that a signal from SI1 is transmitted to the flip-flop 1202 via the multiplexer 1204, next, a clock is applied to CDR so that a signal input from SI1 is stored in the flip-flop 1202 and the stored signal is output to SO1.

For operation for setting a signal output from PO, first, after a signal input from SI1 is stored in the flip-flop 1202 using the operation for transferring the signal input from SI1 to SO1, a signal output from the flip-flop 1203 is transmitted to PO using signals from MODE as one set, afterward, a clock is applied to UDR so that the signal stored in the flip-flop 1202 is stored in the flip-flop 1203 and the stored signal is output to PO.

Next, the operation in the parallel test mode will be described. After ‘1’ is applied to the MODE terminal so that the effect of a signal input from PI is not transmitted to PO and a signal stored in the flip-flop 1203 is transmitted to PO, the following operation is executed.

To execute input signal observing operation, first, ‘0’ is applied to SDR so that a signal from PI is transmitted to the flip-flop 1202 via the multiplexer 1204, next, a clock is applied to CDR so that the signal from PI is stored in the flip-flop 1202 and the stored signal is output to SO1.

To execute observed signal transferring operation, first, ‘1’ is applied to SDR so that a signal from SI1 is transmitted to the flip-flop 1202 via the multiplexer 1204, next, a clock is applied to CDR so that the signal from SI1 is stored in the flip-flop 1202 and the stored signal is output to SO1.

To execute output signal setting operation and output signal transferring operation, a clock is applied to UDR so that a signal input from SI2 is stored in the flip-flop 1203 and the stored signal is output to PO and SO2.

During the test mode, as an input data observing scan path from SI1 to SO1 and an output data setting scan path from SI2 to SO2 are different and are also independent in relation to control, observed signal transferring operation and output signal setting operation can be independently executed and similarly, input signal observing operation and output signal setting operation can be independently executed. Also, the observed signal transferring operation and the output signal transferring operation can be independently executed, and similarly, the input signal observing operation and the output signal transferring operation can be independently executed.

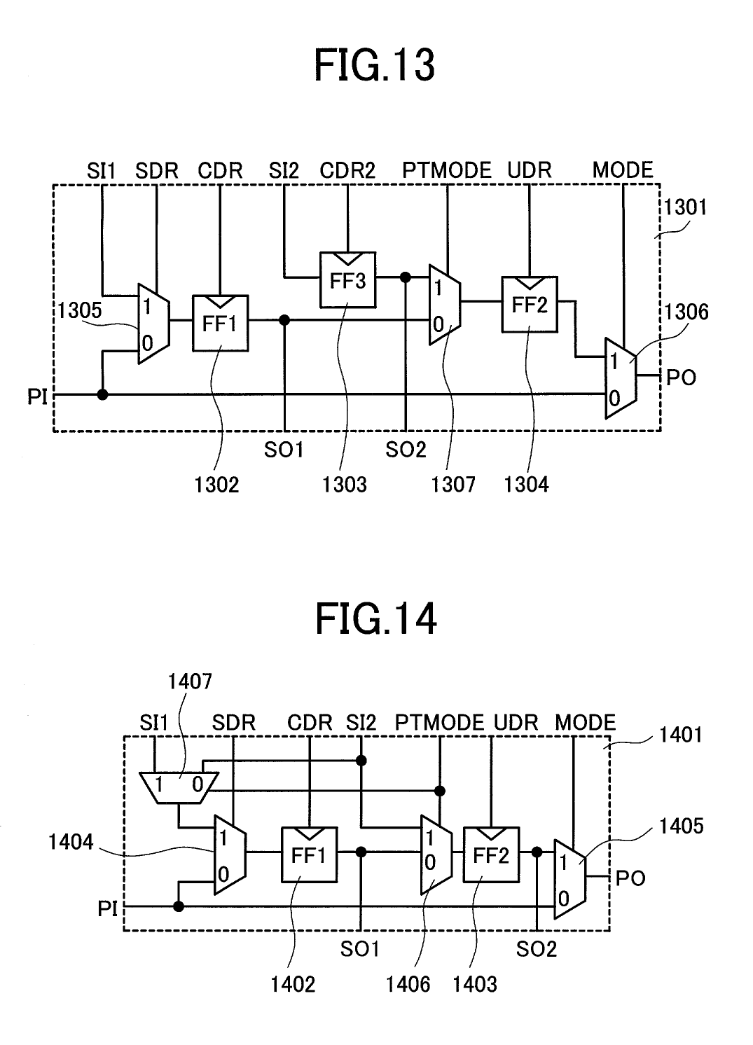

FIG. 13 shows another concrete example of the configuration of the embodiment shown in FIG. 11. A reference number 1301 denotes a cell having scan functions, PI denotes an input terminal, PO denotes an output terminal, SI1 denotes an input terminal for test, SI2 denotes an input terminal for test, SO1 denotes an output terminal for test, SO2 denotes an output terminal for test, 1302 denotes a flip-flop for storing a signal input from PI and a signal input from SI1, CDR denotes a terminal for inputting a clock signal to the flip-flop 1302, 1303 denotes a flip-flop for storing a signal input from SI2, CDR2 denotes a terminal for inputting a clock signal to the flip-flop 1303, 1304 denotes a flip-flop for storing a signal output to PO, UDR denotes a terminal for inputting a clock signal to the flip-flop 1304, 1305 denotes a multiplexer for switching storing a signal input from PI in the flip-flop 1302 and storing a signal input from SI1 in the flip-flop 1302, SDR denotes a terminal for inputting a control signal for selection in the multiplexer 1305, 1306 denotes a multiplexer for switching a normal operational mode in which a signal input from PI is output to PO and a test mode, MODE denotes a terminal for inputting a control signal for selection in the multiplexer 1306, 1307 denotes a multiplexer for switching storing a signal output from the flip-flop 1302 in the flip-flop 1304 and storing a signal output from the flip-flop 1303 in the flip-flop 1304 and PTMODE denotes a terminal for inputting a control signal for selection in the multiplexer 1306.

The example shown in FIG. 13 of the figuration has configuration in which the flip-flop for transfer and the flip-flop for setting an output signal are separately provided so that a signal output from PO is unchanged while an output signal is transferred in a parallel test mode based upon the example shown in FIG. 11 of the configuration. As control in the normal operational mode and input signal observing operation and observed signal transferring operation in a compatible mode with a boundary scan and the parallel test mode are the same as those in the example shown in FIG. 12 of the configuration, the description is omitted.

For the output signal transferring operation in the parallel test mode, after ‘1’ is applied to the MODE terminal so that the effect of a signal input from PI is not transmitted to PO and a signal stored in the flip-flop 1304 is transmitted to PO, a clock is applied to CDR2 so that a signal input from SI2 is stored in the flip-flop 1304 and the stored signal is output to SO2.

For the output signal setting operation in the parallel test mode, after ‘1’ is applied to the MODE terminal so that the effect of a signal input from PI is not transmitted to PO, a clock is applied to UDR so that a signal stored in the flip-flop 1303 is stored in the flip-flop 1304 and the signal stored in the flip-flop 1304 is output to PO.

FIG. 14 shows further another concrete example of the configuration of the embodiment shown in FIG. 11. A reference number 1401 denotes a cell having scan functions, PI denotes an input terminal, PO denotes an output terminal, SI1 denotes an input terminal for test, SI2 denotes an input terminal for test, SO1 denotes an output terminal for test, SO2 denotes an output terminal for test, 1402 denotes a flip-flop for storing a signal input from PI and a signal input from SI1, CDR denotes a terminal for inputting a clock signal to the flip-flop 1402, 1403 denotes a flip-flop for storing a signal input from SI2 or a signal output from the storage element 1402, UDR denotes a terminal for inputting a clock signal to the flip-flop 1403, 1404 denotes a multiplexer for switching storing a signal input from PI in the flip-flop 1402 and storing a signal input from SI1 in the flip-flop 1402, SDR denotes a terminal for inputting a control signal for selection in the multiplexer 1404, 1405 denotes a multiplexer for switching a normal operational mode in which a signal input from PI is output to PO and a test mode, MODE denotes a terminal for inputting a control signal for selection in the multiplexer 1405, 1406 denotes a multiplexer for switching storing a signal output from the flip-flop 1402 in the flip-flop 1403 and storing a signal input from SI2 in the flip-flop 1403 and PTMODE denotes a terminal for inputting a control signal for selection in the multiplexer 1406.

A reference number 1407 denotes a multiplexer for switching paths so that a signal path from SI2 to SO1 is a scan path when ‘0’ is applied to PTMODE to turn to the compatible mode with a boundary scan. As circuit operation is the same except that SI2 is used in place of SI1 in the compatible mode with a boundary scan, the description is omitted.

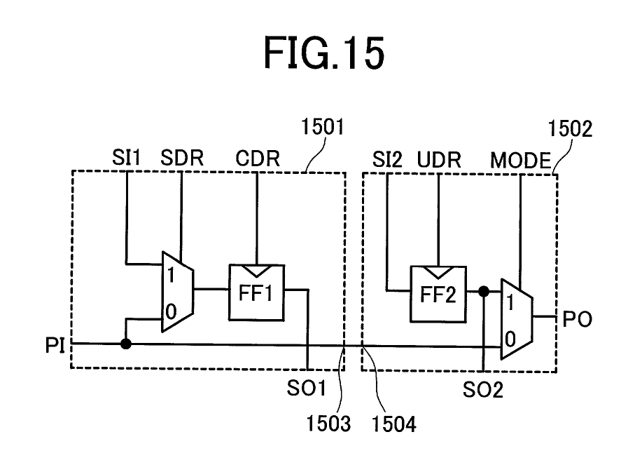

FIG. 15 shows an example of a test circuit in which the cell having scan functions shown in FIG. 9 is formed by two cells. A reference number 1501 denotes a cell used for observing a signal input from PI, 1502 denotes a cell used for setting output to PO and as shown in FIG. 15, the cell 1501 and the cell 1502 are arranged adjacently. The cell 1501 and the cell 1502 are connected via a terminal 1503 and a terminal 1504. As a control method and the operation are the same as those of the cell having scan functions shown in FIG. 9, the description is omitted.

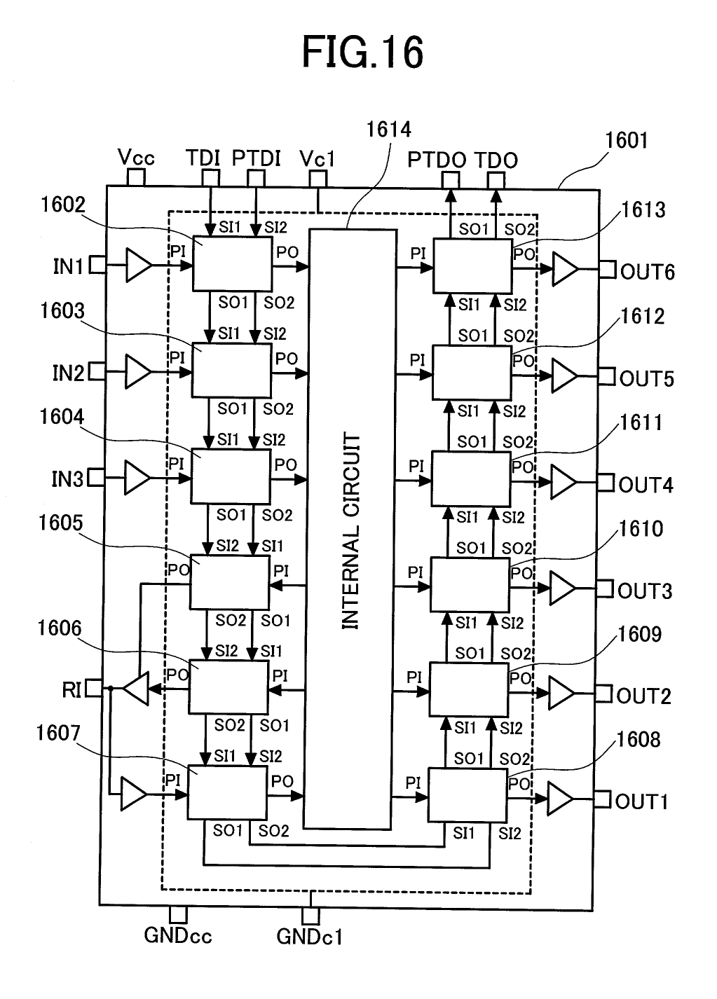

FIG. 16 shows an embodiment of a test circuit using the cell having scan functions according to the invention. A reference number 1601 denotes a semiconductor integrated circuit provided with the test circuit, 1602 to 1613 denote the cell having scan functions shown as the reference number 101 in FIG. 1, 1614 denotes an internal circuit in an area under a test, Vcc and GNDcc denote a power supply terminal for supplying power to an I/O buffer which is an object of the test and a grounding terminal, Vc1 and GNDc1 denote a power supply terminal for supplying power to the internal circuit and a grounding terminal, IN1 to IN3 denote an external input terminal, OUT1 to OUT6 denote an external output terminal, B1 denotes an external bi-directional terminal, TD1 and PTD1 denote an external input terminal for the test, and TDO and PTDO denote an external output terminal for the test.

The cells having scan functions 1602 to 1604 and 1607 connect each I/O buffer and PI of each cell having scan functions to observe a signal input from the external input terminal via the I/O buffer and a signal input from the external bi-directional terminal via the I/O buffer and connect PO of each cell having scan functions and each input terminal of the internal circuit to set a signal input to the internal circuit. The cells having scan functions 1605, 1606 and 1608 to 1613 connect each I/O buffer and PO of each cell having scan functions to set a signal output to the I/O buffer and connect each output terminal of the internal circuit and PI of each cell having scan functions to measure a signal output from the internal circuit.

A scan path in this embodiment is formed by the following two. For one, as the observation of a signal input from the external input terminal via the I/O buffer and the setting of a signal output to the I/O buffer are performed via one scan path, the input data scan path of the cells having scan functions 1602 to 1604 and 1607 and the output data scan path of the cells having scan functions 1605, 1606 and 1608 to 1613 are serially connected to be a scan path from the external input terminal for test TD1 to the external output terminal for test TDO.

For the other, as the setting of a signal input to the internal circuit and the observing of a signal output from the internal circuit are performed via one scan path, the output data scan path of the cells having scan functions 1602 to 1604 and 1607 and the input data scan path of the cells having scan functions 1605, 1606 and 1608 to 1613 are serially connected to be a scan path from the external input terminal for the test PTD1 to the external output terminal for the test PTDO.

The scan path from TD1 to TDO is called an outside scan path and the scan path from PTD1 to PTDO is called an inside scan path.

Next, the test of an I/O device will be described. The test of the I/O device basically includes a test of whether the input buffer precisely fetches a signal applied to the external input terminal and can output it to the internal circuit or not and a test of whether a signal set to the output buffer is precisely output to the external terminal or not.

A method of making a test of the I/O device using the outside scan path will be described below. To make a test of each input buffer connected to the external input terminals IN1 to IN3, first, a test signal is applied to IN2. Next, input signal observing operation is applied to the cells having scan functions 1602 to 1504 and a signal output from each input buffer is stored in the cells having scan functions 1602 to 1604. Next, observed signal transferring operation is applied to the cells having scan functions 1602 to 1604 and 1607, output signal transferring operation is applied to the cells having scan functions 1605, 1606 and 1608 to 1613, the stored signals are output from TDO via the outside scan path and it is determined whether they are normal or not.

To make a test of each output buffer connected to the external output terminals OUT1 to OUT6, first, a test signal is applied to TDI, observed signal transferring operation is applied to the cells having scan functions 1602 to 1604 and 1607, output signal transferring operation is applied to the cells having scan functions 1605, 1606 and 1608 to 1613 and a setting signal is transferred to the cells having scan functions corresponding to each output buffer for the test signal to be set. Next, output signal setting operation is applied to the cells having scan functions 1608 to 1613 and a signal is set to each output buffer.

Next, a signal output from the output buffer is observed and it is determined whether the signal is normal or not. In a test of a tri-state buffer connected to the external bi-directional terminal BI, as described above, a signal is set to a control input terminal and an input terminal of the tri-state buffer using the outside scan path, a signal output from BI is observed and it is determined whether the signal is normal or not. In a test of the input buffer connected to the external bi-directional terminal BI, ‘0’ is set to the control input terminal of the tri-state buffer, next, a test signal is applied to the BI terminal, next, input signal observing operation is applied, next, a stored signal is output from TDO via the outside scan path and it is determined whether the stored signal is normal or not.

A method of making a test of the internal circuit using the inside scan path will be described below. For the test of the internal circuit, a test signal is applied to the input terminal of the internal circuit and as a result, it is determined by observing a signal output from the output terminal of the internal circuit whether the signal is normal or not. First, a test signal is applied to PTDI, output signal transferring operation is applied to the cells having scan functions 1602 to 1604 and 1607, input signal transferring operation is applied to the cells having scan functions 1605, 1606 and 1608 to 1613 and a setting signal is transferred to the cell having scan functions corresponding to the input terminal for a test signal to be set of the internal circuit.

Next, output signal setting operation is applied to the cells having scan functions 1602 to 1604 and 1607 and a test signal is applied to the input terminal of the internal circuit. Next, input signal observing operation is applied to the cells having scan functions 1605, 1606 and 1608 to 1613 and a signal output from each corresponding output terminal of the internal circuit is stored in the cells having scan functions 1605, 1606 and 1608 to 1613. Next, the stored signal is output from PTDO via the inside scan path and it is determined whether the stored signal is normal or not.

As input signal observing operation or observed signal transferring operation and output signal setting operation or output signal transferring operation can be independently executed in each cell having scan functions 1602 to 1613, the test of the I/O device using the outside scan path and the test of the internal circuit using the inside scan path can be executed in parallel.

To measure the output current characteristic and the output impedance characteristic of the output buffer and the input impedance characteristic of the input buffer, the power supply voltage is required to be changed and observed, however, the test of the I/O device and the test of the internal circuit can be made in a state in which the power supply voltage is separately set by separating the power supply system Vcc and GNDcc of the I/O buffer which is an object of the test and the power supply system Vc1 and GNDc1 of the internal circuit as in this embodiment.

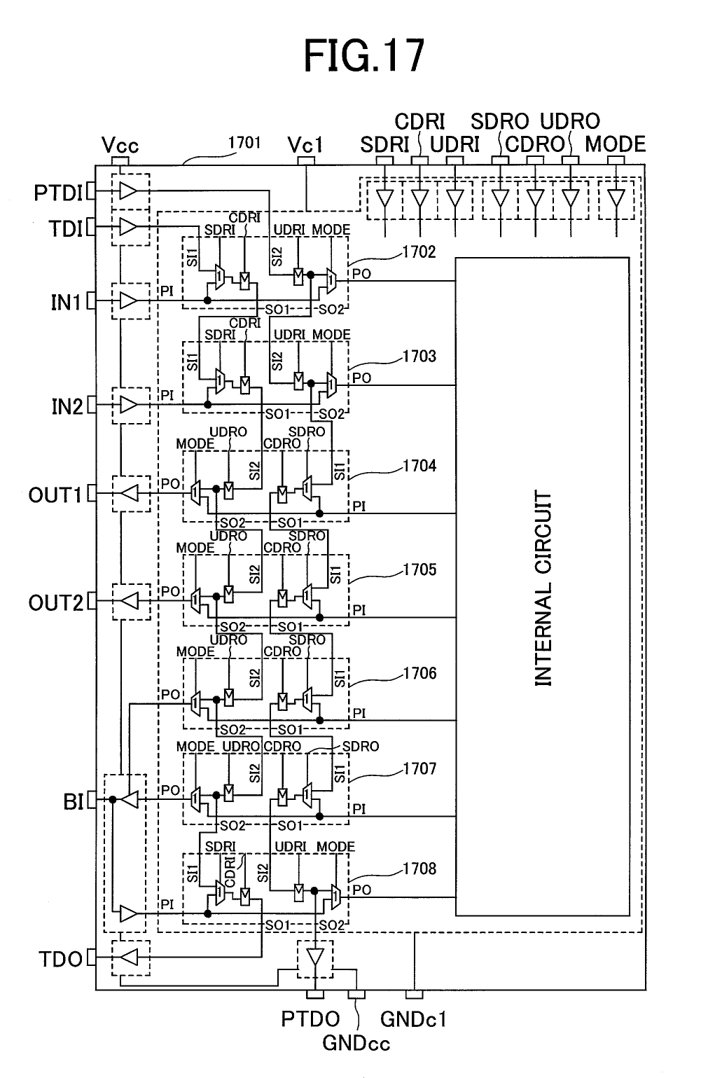

FIG. 17 shows another embodiment of a test circuit using the cell having scan functions 901 shown in FIG. 9. A reference number 1701 denotes a semiconductor integrated circuit provided with a test circuit, 1702 to 1708 denote a cell having scan functions shown as 901 in FIG. 9, Vcc and GNDcc denote a power supply terminal for supplying power to an I/O buffer which is an object of a test and a grounding terminal, Vc1 and GNDc1 denote a power supply terminal for supplying power except the I/O buffer which is the object of the test and a grounding terminal, IN1 and IN2 denote an external input terminal, OUT1 and OUT2 denote an external output terminal, BI denotes an external bi-directional terminal, TDI and PTDI denote an external input terminal for a test, TDO and PTDO denote an external output terminal for the test, and SDRI, CDRI, UDRI, SDRO, CDRO, UDRO and MODE denote an input terminal for controlling the test. A signal from a control terminal for the test is applied to the corresponding terminal having the same name of each cell having scan functions 1702 to 1708.

The circuit equivalent to this embodiment has a normal operational mode and a test operational mode, and the normal operational mode and the test mode are switched according to a control signal from the MODE terminal. To turn to the normal operational mode, a signal can be transmitted between IN1, IN2, OUT1, OUT2 or BI and an internal circuit by setting ‘0’ to the MODE terminal and selecting a path on which a signal input from the PI terminal of each cell having scan functions 1702 to 1708 is transmitted to the PO terminal. To turn to the test mode, ‘1’ is set to the MODE terminal and a path on which a signal input from the PI terminal of each cell having scan functions 1702 to 1708 is transmitted to the PO terminal is disconnected so that the change of a signal on the I/O side and on the side of the internal circuit has no effect upon each other.

In this embodiment, two scan paths of an outside scan path from the external input terminal for test TDI to the output terminal for test TDO via SI1 and SO1 of 1702, SI1 and SO1 of 1703, SI2 and SO2 of 1704, SI2 and SO2 of 1705, SI2 and SO2 of 1706, SI2 and SO2 of 1707 and SI1 and SO1 of 1708 and an inside scan path from the external input terminal for test PTDI to the output terminal for test PTDO via SI2 and SO2 of 1702, SI2 and SO2 of 1703, SI1 and SO1 of 1704, SI1 and SO1 of 1705, SI1 and SO1 of 1706, SI1 and SO1 of 1707 and SI2 and SO2 of 1708 are provided.

A method of making a test of an I/O device using the outside scan path in the test mode will be described below.

To make the test of the I/O buffer connected to each external input terminal IN1, IN2, signals for the test are set to IN1 and IN2. Next, the signals for the test are stored as observed data in the storage elements 1702 and 1703 on an input data scan path by setting ‘0’ to the SDRI terminal and applying a clock to the CDRI terminal. Next, observed data stored in the next storage element on the outside scan path is transferred by setting ‘1’ to SDRI and simultaneously applying a clock to CDRI and UDRO. It is determined by repeating the transferring operation and observing observed data at TDO whether the observed data is normal or not.

For a test of each I/O buffer connected to the external output terminals OUT1 and OUT2, first, ‘1’ is set to SDRI, next, a test signal to be set to OUT2 is set to TDI and a clock is simultaneously applied to CDRI and UDRO. Next, a test signal to be set to OUT1 is set to TDI and a clock is simultaneously applied to CDRI and UDRO. Next, the simultaneous application of a clock to CDRI and UDRO is repeated twice and the test signals are set in the storage elements 1704 and 1405 on the output data scan path. An output signal from OUT1 and OUT2 according to the set test signal is observed and it is determined whether the output signal is normal or not.

For a test of the tri-state buffer connected to the external bi-directional terminal BI, first, ‘1’ set to SDRI. Next, a test signal to be set to a data input terminal of the tri-state buffer is set to TDI and a clock is simultaneously applied to CDRI and UDRO. Next, a test signal to be set to a control input terminal of the tri-state buffer is set and a clock is simultaneously applied to CDRI and UDRO. Next, the simultaneous application of a clock to CDRI and UDRO is repeated four times and the test signals are set in the storage elements 1706 and 1707 on the output data scan path. An output signal or impedance at BI according to the set signal is observed and it is determined whether it is normal or not.

For a test of the input buffer connected to the external bi-directional terminal BI, first, ‘1’ is set to SDRI. Next, ‘0’ is set to TDI and a clock is simultaneously applied to CDRI and UDRO. Next, the simultaneous application of a clock to CDRI and UDRO is repeated four times and a test signal ‘0’ is set in the storage element 1706 on the output data scan path. Next, a signal is stored in the storage element 1708 on the input data scan path as observed data by setting the signal for the test to the BI terminal, setting ‘0’ to SDRI and applying a clock to CDRI. It is determined based upon the stored observed data output from TDO whether the signal for the test is normal or not.

A method of making an internal circuit test using the inside scan path in the test mode will be described below.

First, ‘1’ is set to SDRO and next, a signal for the test to be set in the storage element 1708 on the output data scan path is set to PTDI. Next, the simultaneous application of a clock to UDRI and CDRO is repeated five time. Next, a signal for the test to be set in the storage element 1703 on the output data scan path is set to PTDI and the simultaneous application of a clock to UDRI and CDRO is performed once. Next, a signal for the test to be set in the storage element 1702 on the output data scan path is set to PTDI and the simultaneous application of a clock to UDRI and CDRO is performed once. Next, ‘0’ is set to SDRO, a clock is applied to CDRO and an output signal from the internal circuit is stored in the storage elements 1704 to 1707 on the input data scan path. Next, ‘1’ is set to SDRO, the simultaneous application of a clock to UDRI and CDRO is repeated four times, stored data is observed at PTDO and it is determined whether the stored data is normal or not.

In this embodiment, as the outside scan path for making the test of the I/O device and the inside scan path for making the test of the internal circuit are also different in a data transfer path and a control signal, each can be independently operated, and the test of the I/O device and the test of the internal circuit can be executed in parallel. As described in this embodiment, power supply voltage can be separately changed in the test of the I/O buffer and the test of the internal circuit by separating the power supply system of the I/O buffer which is the object of the test and the power supply system of parts except the I/O buffer.

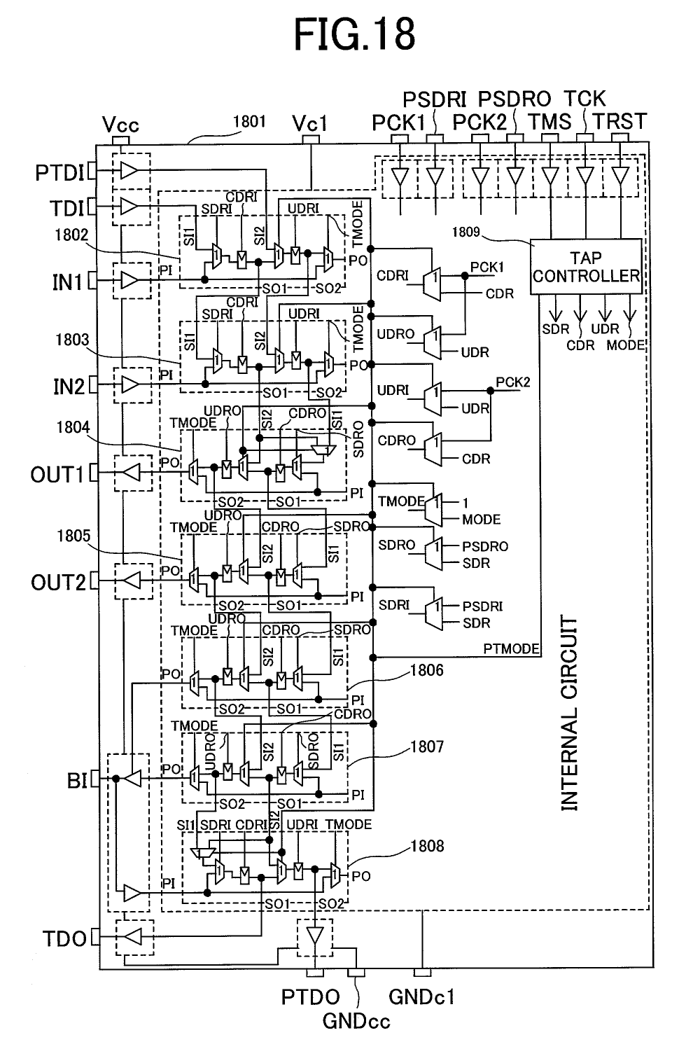

FIG. 18 shows further another embodiment of the test circuit using the cell having scan functions shown as 1202 in FIG. 12 and as 1401 in FIG. 14.

A reference number 1801 denotes a semiconductor integrated circuit provided with a scan circuit, 1802, 1803 and 1805 to 1807 denote the cell having scan functions shown as 1201 in FIG. 12, 1804 and 1808 denote the cell having scan functions shown as 1401 in FIG. 14, 1809 denotes a TAP controller that controls the scan circuit in this embodiment, Vcc and GNDcc denote a power supply terminal for supplying power to an I/O buffer which is an object of a test and a grounding terminal, Vc1 and GNDc1 denote a power supply terminal for supplying power except the I/O buffer which is the object of the test and a grounding terminal, IN1 and IN2 denote an external input terminal, OUT1 and OUT2 denote an external output terminal, BI denotes an external bi-directional terminal, TDI and PTDI denote an external input terminal for test, TDO and PTDO denote an external output terminal for test, PCK1, PSDRI, PCK2, PSDRO, TMS, TCK and TRST denote a control input terminal for test, PTMODE, SDR, CDR, UDR and MODE denote test control signals output by the TAP controller, and SDRI, CDRI, UDRI, SDRO, CDRO, UDRO and TMODE denote control signals for controlling the cell having scan functions. Signals from the control input terminals for test PCK1, PSDRI, PCK2 and PSDRO to the internal circuit and each control output signal PTMODE, SDR, CDR, UDR, MODE from the TAP controller shall be connected to the corresponding signal conductor having the same name in the circuit. The output PO of 1802, 1803 and 1808 and the input PI of 1804 to 1807 shall be connected to the input terminal and the output terminal of the internal circuit.

The circuit in this embodiment has three types of operational modes of a normal operational mode, a compatible mode with a boundary scan and a parallel test mode and these are switched according to control signals PTMODE and MODE output by the TAP controller. In this embodiment, the parallel test mode in which the TAP controller outputs ‘1’ for a PTMODE signal is added as a user test mode in addition to the specifications of a boundary scan. The control of the TAP controller is executed according to a standard described in IEEE 1149.1.

As PTMODE and MODE are made ‘0’ in the normal mode, a path on which a signal input from the PI terminal of each cell having scan functions 1802 to 1808 is transmitted to the PO terminal is selected and a signal can be transmitted between IN1, IN2, OUT1, OUT2 or BI and the internal circuit.

In the compatible mode with a boundary scan, PTMODE is made ‘0’, SDR, CDR, UDR and MODE output a signal similar to a control signal to a boundary scan circuit and the scan circuit executes operation similar to a boundary scan.

In the parallel test mode, PTMODE is made ‘1’ and the scan circuit is controlled according to a signal output from the control input terminals for the test PCK1, PSDRI, PCK2 and PSDRO. As ‘1’ is set to the input terminal TMODE of each cell having scan functions 1802 to 1808 according to PTMODE, a path on which a signal input from the PI terminal of each 1802 to 1808 is transmitted to the PO terminal is disconnected and the change of a signal on the I/O side and the side of the internal circuit has no effect upon each other.

In the compatible mode with a boundary scan in this embodiment, a boundary scan path from the external input terminal for the test TDI to the output terminal for the test TDO via SI1 and SO1 of 1802, SI1 and SO1 of 1803, SI2 and SO of 1804, SI1 and SO1 of 1805, SI1 and SO1 of 1806, SI1 and SO1 of 1807 and SI2 and SO1 of 1808 is only one scan path.

In the parallel test mode, a scan path is divided into two of an outside scan path from the external input terminal for the test TDI to the output terminal for the test TDO via SI1 and SO1 of 1802, SI1 and SO1 of 1803, SI2 and SO2 of 1804, SI2 and SO2 of 1805, SI2 and SO2 of 1806, SI2 and SO2 of 1807 and SI1 and SO1 of 1808 and an inside scan path from the external input terminal for the test PTDI to the output terminal PTDO for the test PTDO via SI2 and SO2 of 1802, SI2 and SO2 of 1803, SI1 and SO1 of 1804, SI1 and SO1 of 1805, SI1 and SO1 of 1806, SI1 and SO1 of 1807 and SI2 and SO2 of 1808.

A method of making a test of an I/O device in the compatible mode with a boundary scan will be described below. The test of the I/O device is executed in an EXTEST mode.

To make the test of each I/O device connected to the external input terminals IN1 and IN2, first, MODE is set to 0. Next, signals for the test is set to IN1 and IN2. Next, SDR is set to 0 is set to SDR, a clock signal is output to CDR and the signals output from each input buffer are stored in the storage elements 1802 and 1803 on the input data scan path as observed data. Next, SDR is set to 1, a clock is output to CDR and the observed data is transferred to the next storage element on the boundary scan path. It is determined by repeating the transferring operation and observing the observed data at TDO whether the observed data is normal or not.

For the test of each I/O buffer connected to the external output terminals OUT1 and OUT2, first, MODE is set to 0, SDR is set to 1, next, a test signal to be set to OUT2 is set to TDI and a clock is output to CDR. Next, a test signal to be set to OUT1 is set to TDI and a clock is output to CDR. Next, a clock is output to CDR twice and the test signals are set in the storage elements 1804 and 1805 on the input data scan path. Next, MODE is set to 1 and a clock is output to UDR. The test signals are set in the storage elements 1804 and 1805 on the output data scan path by the output of the clock. Next, an output signal from OUT1 and OUT2 based upon the set test signal is observed and it is determined whether the output signal is normal or not.

For a test of a tri-state buffer connected to the external bi-directional terminal BI, first, MODE is set to 0 and SDR is set to 1. Next, a test signal to be set to a data input terminal of the tri-state buffer is set to TDI and a clock is output to CDR. Next, a test signal to be set to a control input terminal of the tri-state buffer is set and a clock is output to CDR. Next, a clock is output to CDR four times and the test signals are set in the storage elements 1806 and 1807 on the input data scan path. Next, MODE is set to 1 and a clock is output to UDR. The test signals are set in the storage elements 1806 and 1807 on the output data scan path by the output of the clock. An output signal or impedance at BI based upon the set signal is observed and it is determined whether the output signal or the impedance is normal or not.

For a test of the input buffer connected to the external bi-directional terminal BI, first, MODE is set to 0, SDR is set to 1, next, ‘0’ is set to TDI and a clock is output to CDR. Next, a clock is output to CDR four times and a test signal is set in the storage element 1806 on the input data scan path. Next, MODE is set to 1 and a clock is output to UDR. The test signal is set in the storage element 1806 on the output data scan path by the output of the clock and the output of the tri-state buffer is fixed to high impedance. Next, a signal for the test is set to the BI terminal, SDR is set to 0, a clock is output to CDR and the signal is stored in the storage element 1808 on the input data scan path as observed data. It is determined based upon the observed data output from TDO whether the signal is normal or not.

A method of making a test of the internal circuit in the compatible mode with a boundary scan will be described below. The test of the internal circuit is executed in an INTEST mode. Basically, the test is made by applying test data to the internal circuit on the boundary scan path and observing the next output response of it on the boundary scan path.

First, MODE is set to 0, SDR is set to 1 and next, a signal for the test to be set in the storage element 1808 on the output data scan path is set to TDI. Next, a clock is output to CDR five times, next, a signal for the test to be set in the storage element 1803 on the output data scan path is set to TDI and a clock is output to CDR. Next, a signal for the test to be set in the storage element 1802 on the output data scan path is set and a clock is output to CDR. Next, MODE is set to 1, a clock is output to UDR and the signals set in the storage elements 1802, 1803 and 1808 on the output data scan path are transferred to the storage elements on the input data scan path. Hereby, the test signal is applied to the internal circuit from each PO of 1802, 1803 and 1808. Next, SDR is set to 0 and a clock is output to CDR. Hereby, an output signal from the internal circuit is stored in the storage elements 1804 to 1807 on the input data scan path. Next, MODE is set to 0, SDR is set to 1, a clock is output to CDR four times, the output signal from the internal circuit is observed at the external terminal for the test TDO and it is determined whether the output signal is normal or not.

A method of making a test of the I/O device in the parallel test mode will be described below. For the test of the I/O device, the outside scan path is used. To make the test of each I/O buffer connected to the external input terminals IN1 and IN2, a signal for the test is set to IN1 and IN2. Next, the signals are stored in the storage elements 1802 and 1803 on the input data scan path as observed data by setting ‘0’ to the PSDRI terminal and applying a clock to the PCK1 terminal. Next, observed data stored in the next storage element on the outside scan path is transferred by setting ‘1’ to PSDRI and applying a clock to PCK1. It is determined by repeating the transferring operation and observing observed data at TDO whether the signal is normal or not.

For the test of each I/O buffer connected to the external output terminals OUT1 and OUT2, first, ‘1’ is set to PSDRI, next, a test signal to be set to OUT2 is set to TDI and a clock is applied to PCK1. Next, a test signal to be set to OUT1 is set to TDI and a clock is applied to PCK1. Next, the application of a clock to PCK1 is repeated twice and the test signals are set in the storage elements 1804 and 1805 on the output data scan path. Each output signal from OUT1 and OUT2 based upon each set test signal is observed and it is determined whether each output signal is normal or not.

For the test of the tri-state buffer connected to the external bi-directional terminal BI, first, ‘1’ is set to PSDRI, next, a test signal to be set to the data input terminal of the tri-state buffer is set to TDI and a clock is simultaneously applied to CDRI and UDRO. Next, a test signal to be set to the control input terminal of the tri-state buffer is set and a clock is simultaneously applied to CDRI and UDRO. Next, the application of a clock to PCK1 is repeated four times and the test signals are set in the storage elements 1806 and 1807 on the output data scan path. Output signals or impedance at BI based upon the set signals are/is observed and it is determined whether the output signals are normal or not.

For a test of an input buffer connected to the external bi-directional terminal BI, first, ‘1’ is set to PSDRI, next, ‘0’ is set to TDI and a clock is applied to PCK1. Next, the application of a clock to PCK1 is repeated four times and a test signal ‘0’ is set in the storage element 1806 on the output data scan path. Next, the following signal is stored in the storage element 1808 on the input data scan path as observed data by setting the signal for the test to the BI terminal, setting 101 to PSDRI and applying a clock to PCK1. It is determined based upon the stored observed data output from TDO whether the data is normal or not.

A method of making a test of the internal circuit in the parallel test mode will be described below. For the test of the internal circuit, the inside scan path is used. First, ‘1’ is set to PSDRO and next, a signal for the test to be set in the storage element 1808 on the output data scan path is set to PTDI. Next, the application of a clock to PCK2 is repeated five times. Next, a signal for the test to be set in the storage element 1803 on the output data scan path is set to PTDI and the application of a clock to PCK2 is performed once. Next, a signal for the test to be set in the storage element 1802 on the output data scan path is set to PTDI and the application of a clock to PCK2 is performed once. Next, ‘0’ is set to PSDRO, a clock is applied to PCK2 and an output signal from the internal circuit is stored in the storage elements 1804 to 1807 on the input data scan path. Next, ‘1’ is set to PSDRO, the application of a clock to PCK2 is repeated four times, the stored data is observed at PTDO and it is determined whether the stored data is normal or not.

In this embodiment, as the outside scan path for making the test of the I/O device and the inside scan path for making the test of the internal circuit are also different in a data transfer path and a control signal in the parallel test mode, they can be independently operated, and the test of the I/O device and the test of the internal circuit can be executed in parallel. Also, as shown in this embodiment, power supply voltage can be separately changed in the test of the I/O device and the test of the internal circuit by separating the power supply system of the I/O buffer which is an object of the test and the power supply system of parts except it.

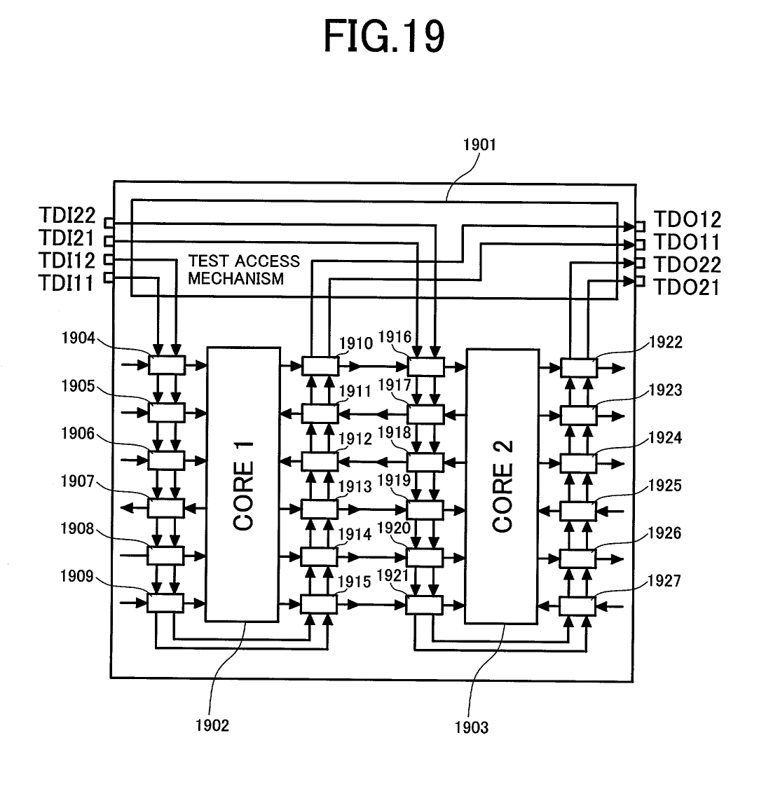

FIG. 19 shows an embodiment of the test circuit using the cell having scan functions 101 shown in FIG. 1 utilizing the core test technique shown in the example of prior art.

A reference number 1901 denotes a test access mechanism for providing access means to an area under a test from the outside of a circuit, 1902 denotes a core 1 which is an area under the test, 1903 denotes a core 2 which is an area under the test, TDI11 and TDI12 denote an external input terminal for test for the core 1, TDI21 and TDI22 denote an external input terminal for test for the core 2, TDO11 and TDO12 denote an external output terminal for test for the core 1, TDO21 and TDO 22 denote an external output terminal for test for the core 2, 1904 to 1927 denote the cell having scan functions shown as 101 in FIG. 1.

Each output terminal PO of the cells having scan functions 1904 to 1906, 1908, 1909, 1911 and 1912 and the input terminal of the core 1 are connected to observe a signal input from the outside of the core 1 to the core 1 and set a signal input to the core 1. Each input terminal PI of the cells having scan functions 1907, 1910 and 1913 to 1915 and the output terminal of the core 1 are connected to observe a signal output from the core 1 and set a signal output to the outside of the core 1 in place of a signal output from the core 1. Each output terminal PO of the cells having scan functions 1916, 1919 to 1921, 1925 and 1927 and the input terminal of the core 2 are connected to observe a signal input from the outside of the core 2 to the core 2 and set a signal input to the core 2. Each input terminal PI of the cells having scan functions 1917, 1918, 1922 to 1924 and 1926 and the output terminal of the core 2 are connected to observe a signal output from the core 2 and set a signal output to the outside of the core 2 in place of a signal output from the core 2.

A scan path in this embodiment is composed of the following four.

The first is a scan path which serially connects an input data scan path including the cells having scan functions 1904 to 1906, 1908, 1909, 1911 and 1912 and an output data scan path including the cells having scan functions 1907, 1910, 1913 to 1915 and via which test data is output from the external input terminal for the test TDI11 to the external output terminal for the test TDO11 so as to measure a signal input from the outside of the core 1 to the core 1 and set a signal output to the outside of the core 1 in place of a signal output from the core 1 via one scan path and is called the outside scan path of the core 1.

The second is a scan path which serially connects an output data scan path including the cells having scan functions 1904 to 1906, 1908, 1909, 1911 and 1912 and an input data scan path including the cells having scan functions 1907, 1910 and 1913 to 1915 and via which test data is output from the external input terminal for the test TDI12 to the external output terminal for the test TDO12 so as to set a signal input to the core 1 and observe a signal output from the core 1 via one scan path and is called the inside scan path of the core 1.

The third is a scan path which serially connects an input data scan path including the cells having scan functions 1916, 1919 to 1921, 1925 and 1927 and an output data scan path including the cells having scan functions 1917, 1918, 1922 to 1924 and 1926 and via which test data is output from the external input terminal for the test TDI21 to the external output terminal for the test TDO21 so as to observe a signal input from the outside of the core 2 to the core 2 and set a signal output to the outside of the core 2 in place of a signal output from the core 2 via one scan path and is called the outside scan path of the core 2.

The fourth is a scan path which serially connects an output data scan path including the cells having scan functions 1916, 1919 to 1921, 1925 and 1027 and an input data scan path including the cells having scan functions 1917, 1918, 1922 to 1924 and 1926 and via which test data is output from the external input terminal for the test TDI22 to the external output terminal for the test TDO22 so as to set a signal input to the core 2 and observe a signal output from the core 2 via one scan path and is called the inside scan path of the core 2.

A method of testing the core 1 which is an area under the test using the inside scan path of the core 1 will be described below. For the test of the core 1, it is determined by applying a test signal to the input terminal of the core 1 and observing a signal output from the output terminal of the core 1 as a result whether the observed test signal is normal or not.

First, a test signal is applied to TDI12, output signal transferring operation is applied to the cells having scan functions 1904 to 1906, 1908, 1909, 1911 and 1912, input signal transferring operation is applied to the cells having scan functions 1907, 1910 and 1913 to 1915 and a setting signal is transferred to the cell having scan functions corresponding to the input terminal of the core 1 for the test signal to be set. Next, output signal setting operation is applied to the cells having scan functions 1904 to 1906, 1908, 1909, 1911 and 1912 and a test signal is applied to the input terminal of the core 1. Next, input signal observing operation is applied to the cells having scan functions 1907, 1910 and 1913 to 1915 and signals output from the output terminal of the core 1 are stored in 1907, 1910 and 1913 to 1915. Next, transferring operation similar to the operation in setting the test signal is executed, the stored signals are transferred to TD012 via the inside scan path of the core 1, output signals acquired at TDO12 are observed and it is determined whether they are normal or not.

As a method of testing the core 2 which is an area under the test using the inside scan path of the core 2 is acquired by only applying the method of the core 1 to the inside scan path of the core 2, the description is omitted.

A method of testing an area between the core 1 and the core 2 which are areas under the test using the outside scan path of the core 1 and the outside scan path of the core 2 will be described below. For the test of the area between the core 1 and the core 2, it is determined by applying a test signal to the cell having scan functions existing between the core 1 and the core 2 and observing it whether the observed test signal is normal or not.

First, a test signal is applied to TDI11 and TDI21 and is transferred to the cells having scan functions for the test signal to be set of the core 1 and the core 2. Next, output signal setting operation is applied to the transferred cells and the test signal is output to the area between the core 1 and the core 2. Next, input signal observing operation is applied to the cell having scan functions influenced by the output test signal and the output test signal is stored as a result of the test. Next, the stored result of the test is transferred to TDO11 and TDO21 via the outside scan paths of the core 1 and the core 2, output signals acquired at TDO11 and TDO21 are observed and it is determined whether they are normal or not.

In this embodiment, as the inside scan paths used for the tests of the core 1 and the core 2 and the outside scan paths used for the test of the area between the core 1 and the core 2 can be independently operated in parallel and the inside scan path of the core 1 and the inside scan path of the core 2 can be also independently operated in parallel, the test of the core 1, the test of the core 2 and the test of the area between the core 1 and the core 2 can be independently executed in parallel.

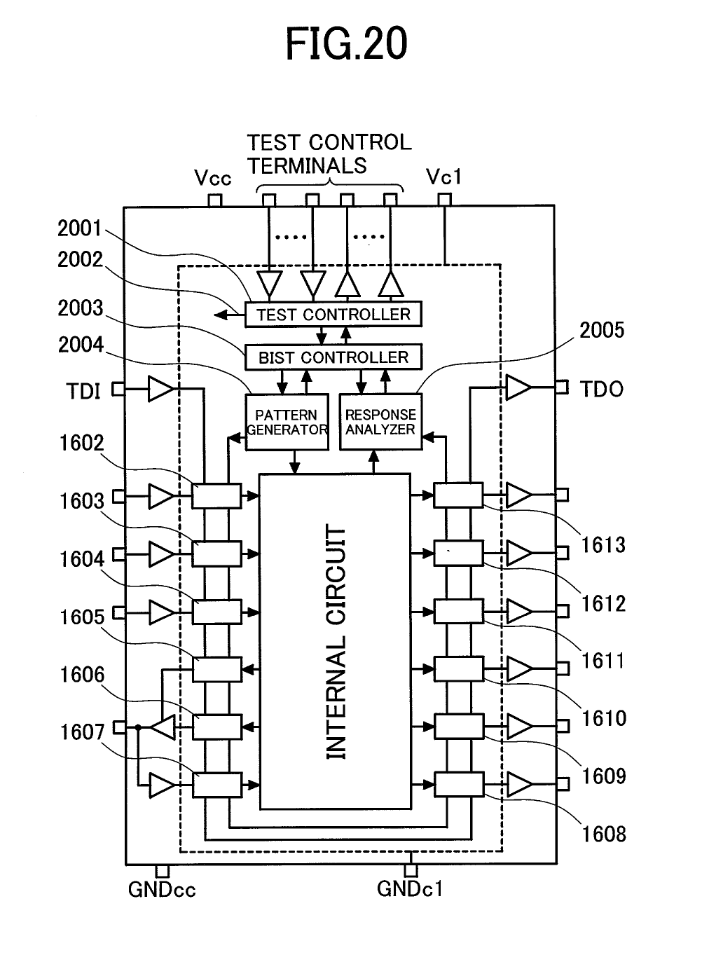

FIG. 20 shows configuration that a BIST circuit is connected to the inside scan path from PTDI to PTDO in the embodiment shown in FIG. 16 so as to make the test of an internal circuit.

A reference number 2001 denotes a test controller that receives input from a test control terminal and controls a scan circuit and a BIST controller, 2002 denotes a control signal for a scan circuit output by the test controller, 2003 denotes a BIST controller that controls the BIST circuit, 2004 denotes a pattern generator forming the BIST circuit, 2005 denotes a response analyzer forming the BIST circuit, Vcc and GNDcc denote a power supply terminal for supplying power to an I/O buffer under the test and a grounding terminal, Vc1 and GNDc1 denote a power supply terminal for supplying power to the internal circuit and a grounding terminal, TDI denotes an external input terminal for the test and TDO denotes an external output terminal for the test.

In this embodiment, as described in the embodiment shown in FIG. 16, the test of the I/O device can be made using an outside scan path from TDI to TDO and the test of the internal circuit is made using an inside scan path from the output of the pattern generator 2004 in the BIST circuit to input to the response analyzer in the BIST circuit. Also, as the outside scan path and the inside scan path can be independently operated, the test of the I/O device can be made in parallel while the test of the internal circuit is automatically made using BIST.

To measure the output current characteristic and the output impedance characteristic of the output buffer and the input impedance characteristic of the input buffer, power supply voltage is required to be changed and observed, however, power supply voltage is separately set in the test of the I/O device and the test of the internal circuit and the tests can be made by separating the power supply system Vcc and GNDcc of the I/O buffer under the test and the power supply system Vc1 and GNDc1 of the internal circuit as in this embodiment.

Generally, time required for the test of the internal circuit has tendency to be longer, compared with the test time of the I/O device and while the test of the internal circuit is made, the number of test items of the I/O device is increased and the precision of the test can be enhanced.

As described above, according to the invention, in the semiconductor integrated circuit provided with scan functions, the parallel execution of the test of the I/O device and the test of the internal circuit and the parallel execution of the test of the core and the test of the area between the cores are enabled, and the reduction of test time and the cost required for the test is enabled.

What is claimed is:

1. A cell having scan functions forming a test circuit of a semiconductor integrated circuit provided with scan test functions, wherein:
a first scan path on which data input to the cell is observed and a second scan path on which data output from the cell is set are separately provided.

2. A cell having scan functions according to claim 1, wherein:
an input terminal and an output terminal respectively connected to the first scan path and an input terminal and an output terminal respectively connected to the second scan path are separately provided.

3. A cell having scan functions forming a test circuit of a semiconductor integrated circuit provided with scan functions, comprising:
a first operational mode in which the observation of data input to the cell and the setting of data output from the cell are performed via one scan path; and
a second operational mode in which a scan path for observing data input to the cell and a scan path for setting data output from the cell are operated in parallel.

4. A cell having scan functions according to claim 3, comprising:
a control terminal for selecting either of the first operational mode and the second operational mode.

5. A test circuit of a semiconductor integrated circuit provided with a cell having scan functions, wherein:
the cell having scan functions is provided with a first scan path for observing input data and a second scan path for setting output data.

6. A test circuit of a semiconductor integrated circuit according to claim 5, wherein:
the cell having scan functions is composed of first and second cells arranged adjacently;
the first scan path is formed in the first cell; and
the second scan path is formed in the second cell.
